(19) United States
(12) Patent Application Publication
(10) Pub. No.: US 2016/0192499 A1
(43) Pub. Date: Jun. 30, 2016

(54) ELECTRONIC DEVICE AND MANUFACTURING METHOD THEREOF

(71) Applicant: HTC Corporation, Taoyuan County (TW)

(72) Inventors: Zhao-Yin Chen, Taoyuan County (TW); Cheng-Yu Chen, Taoyuan County (TW); Yen-Cheng Lin, Taoyuan County (TW); Chung-Chuan Chu, Taoyuan County (TW)

(21) Appl. No.: 14/583,194

(22) Filed: Dec. 26, 2014

(51) Int. Cl. H05K 1/18; H05K 3/30

(52) U.S. Cl. CPC H05K 1/189; H05K 3/30

(57) ABSTRACT

A manufacturing method of an electronic device includes the following steps. A circuit board and at least one electronic component are provided, wherein the electronic component is installed on the circuit board. A protector is formed on the circuit board to cover the electronic component on the circuit board. A housing is formed by insert injection molding to cover the circuit board and the protector.

### BACKGROUND OF THE INVENTION

1. Field of the Invention

The application relates to an electronic device and more particularly relates to an electronic device and a manufacturing method thereof.

2. Description of Related Art

The structure of an electronic product may be roughly divided into components, such as frame, housing, display screen, circuit board, and so on. In the actual production process, the circuit board is assembled onto the frame, and then the display screen, housing, etc. are installed. However, in the case that all the components are independently manufactured and then assembled together, the production process is complicated and longer production time is needed. Therefore, how to simplify the production process is an issue that manufacturers care about.

### SUMMARY OF THE INVENTION

The application provides an electronic device for improving the production yield thereof.

The application provides a manufacturing method of the electronic device, which achieves favorable production yield.

The electronic device of the application includes a circuit board, at least one electronic component, a protector, and a housing. The electronic component is disposed on the circuit board. The protector covers the electronic component and the circuit board. The housing covers the circuit board and the protector.

The manufacturing method of the electronic device of the application includes the following steps. A circuit board and at least one electronic component are provided, wherein the electronic component is installed on the circuit board. A protector is formed on the circuit board to cover the electronic component on the circuit board. A housing is formed by insert injection molding to cover the circuit board and the protector.

Based on the above, according to the application, the protector is formed to cover the electronic component installed on the circuit board first, so as to protect the covered electronic component against the high temperature and high pressure of the subsequent insert injection molding, thereby preventing damage or malfunction of the electronic component. Therefore, in the application, the housing of the electronic device is formed by insert injection molding and covers the circuit board and the electronic component, thereby saving the time required for assembling the housing and the circuit board to each other.

To make the aforementioned and other features and advantages of the invention more comprehensible, several embodiments accompanied with drawings are described in detail as follows.

### BRIEF DESCRIPTION OF THE DRAWINGS

FIG. 1 is a flowchart showing a manufacturing method of an electronic device according to an embodiment of the invention.

FIG. 2A is a schematic view of a circuit board installed with an electronic component in FIG. 1.

FIG. 2B is a schematic view of a protector covering the circuit board and the electronic component in FIG. 1.

FIG. 2C is a schematic view of a housing covering the circuit board and the electronic component in FIG. 1.

### DESCRIPTION OF THE EMBODIMENTS

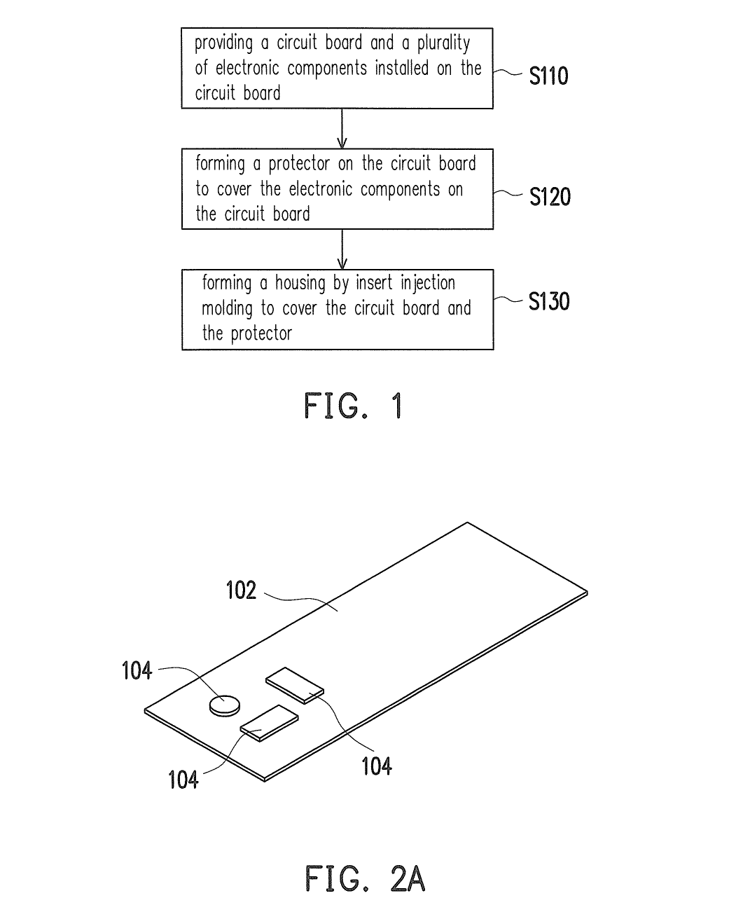

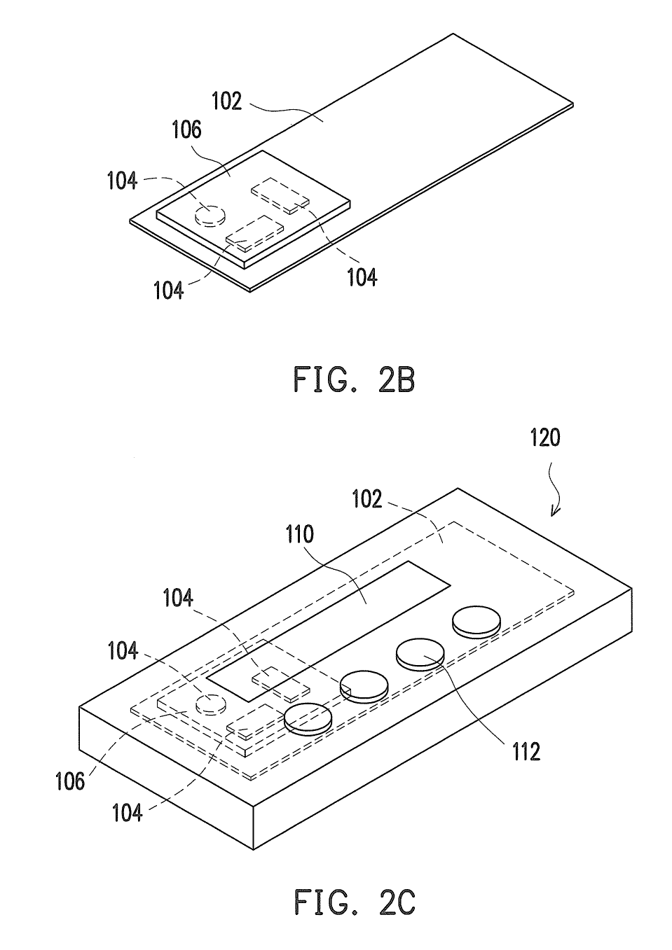

Below a manufacturing method of an electronic device of an embodiment is described with reference to the flowchart of FIG. 1 and FIG. 2A to FIG. 2C.

With reference to FIG. 1 and FIG. 2A, in Step S100, a circuit board 102 and a plurality of electronic components 104 are provided. The electronic components 104 are installed on the circuit board 102. The circuit board 102 may be a flexible circuit board or a printed circuit board.

With reference to FIG. 1 and FIG. 2B, in Step S200, a protector 106 is formed on the circuit board 102 to cover the electronic components 104 on the circuit board 102.

With reference to FIG. 1 and FIG. 2C, in Step S300, a housing 108 is formed by insert injection molding to cover the circuit board 102 and the protector 106, wherein the housing 108 constitutes the appearance of an electronic device 120. A material of the housing 108 may include plastic or rubber.

It should be noted that, because the protector 106 withstands an injection pressure of the insert injection molding for formation of the housing 108, damage of the electronic components 104 covered by the protector is prevented. Meanwhile, the housing 108 may be formed surrounding the circuit board 102 and the electronic components 104 directly by insert injection molding to save the time required for assembling the housing 108 and the circuit board 102 to each other.

In this embodiment, Step S200 of forming the protector 106 may include thermoforming. A working pressure of the thermoforming is lower than a working pressure of the insert injection molding. In addition, a working temperature of the subsequent insert injection molding process does not soften the protector 106. Therefore, the protector 106 is capable of protecting the electronic components 104 in the subsequent insert injection molding process. For example, the working temperature of the thermoforming is in a range of about 180-240 degrees Celsius, and the working pressure is in a range of about 0.01 mpa-5 mpa, preferably 0.01 mpa-1 mpa, and more preferably 0.01 mpa-0.1 mpa. Simply put, the possibility of damage of the electronic components 104 decreases as the working pressure decreases.

In this embodiment, Step S200 of forming the protector 106 may include the following steps. First, an optical adhesive is disposed to cover the circuit board 102 and the electronic components 104 by dispensing. Then, the optical adhesive is irradiated by ultraviolet light and cured to faun the protector. Likewise, the working temperature of the subsequent insert injection molding process does not soften the protector 106 formed by the dispensing process. Therefore, the protector 106 is capable of protecting the electronic components 104 in the subsequent insert injection molding process.

The working temperature of the insert injection molding process is in a range of about 170-200 degrees Celsius, and the working pressure is in a range of about 40 mpa-60 mpa.

In this embodiment, in Step S300 of forming the housing 108 by insert injection molding, the housing 108 further partially covers a display screen 110. Meanwhile, in the step of forming the housing 108 by insert injection molding, the housing 108 further partially covers a plurality of keys 112. The display screen 110 may be a flexible display, such as an organic light-emitting display, an electronic paper display, and so on.

To conclude the above, according to the application, the protector is formed to cover the electronic component installed on the circuit board first, so as to protect the covered electronic component against the high temperature and high pressure of the subsequent insert injection molding, thereby preventing damage or malfunction of the electronic component. Therefore, in the application, the housing of the electronic device is formed by insert injection molding and covers the circuit board and the electronic component, so as to save the time required for assembling the housing and the circuit board to each other.

Although the invention has been described with reference to the above embodiments, it will be apparent to one of the ordinary skill in the art that modifications and variations to the described embodiments may be made without departing from the spirit and scope of the invention. Accordingly, the scope of the invention will be defined by the attached claims not by the above detailed descriptions.

1. An electronic device, comprising:
a circuit board;
at least one electronic component disposed on the circuit board;
a protector covering the at least one electronic component and the circuit board; and
a housing covering the circuit board and the protector.

2. The electronic device according to claim 1, wherein the circuit board comprises a flexible circuit board or a printed circuit board.

3. The electronic device according to claim 1, wherein a melting point of the protector is greater than a melting point of the housing.

4. The electronic device according to claim 1, wherein a material of the housing comprises plastic or rubber.

5. The electronic device according to claim 1, further comprising:
a display screen partially covered by the housing.

6. The electronic device according to claim 1, further comprising:
at least one key partially covered by the housing.

7. The electronic device according to claim 1, wherein the housing is a portion of an appearance of the electronic device.

8. A manufacturing method of an electronic device, comprising:
providing a circuit board and at least one electronic component, wherein the at least one electronic component is installed on the circuit board;
forming a protector on the circuit board to cover the at least one electronic component on the circuit board; and
forming a housing by insert molding to cover the circuit board and the protector.

9. The manufacturing method according to claim 8, wherein the circuit board comprises a flexible circuit board or a printed circuit board.

10. The manufacturing method according to claim 8, wherein the step of forming the protector comprises thermoforming.

11. The manufacturing method according to claim 10, wherein a working temperature and a working pressure of the thermoforming are respectively lower than a working temperature and a working pressure of the insert molding.

12. The manufacturing method according to claim 8, wherein the step of forming the protector comprises:
disposing an optical adhesive to cover the at least one electronic component and the circuit board by dispensing; and
irradiating the optical adhesive by ultraviolet light to cure the optical adhesive.

13. The manufacturing method according to claim 8, wherein a material of the housing includes plastic or rubber.

14. The manufacturing method according to claim 8, wherein in the step of forming the housing by insert molding, the protector further partially covers a display screen.

15. The manufacturing method according to claim 8, wherein in the step of forming the housing by insert molding, the protector further partially covers at least one key.
